(19) United States
(12) Patent Application Publication
(10) Pub. No.: US 2026/0176765 A1
(43) Pub. Date: Jun. 25, 2026

(54) SUBSTRATE PROCESSING METHOD, SUBSTRATE PROCESSING APPARATUS, AND SUBSTRATE PROCESSING SYSTEM

(71) Applicant: Tokyo Electron Limited, Tokyo (JP)

(72) Inventors: Miyako KANEKO, Yamanashi (JP); Naoko SUZUKI, Yamanashi (JP); Tadashi MITSUNARI, Yamanashi (JP); Tenta USHIDA, Yamanashi (JP)

(21) Appl. No.: 19/419,654

(22) Filed: Dec. 15, 2025

(30) Foreign Application Priority Data
Dec. 24, 2024 (JP) 2024-227743

(51) Int. Cl. C23C 16/56; C23C 16/04; C23C 16/26; C23C 16/505; C23C 16/52

(52) U.S. Cl. CPC C23C 16/56; C23C 16/04; C23C 16/26; C23C 16/505; C23C 16/52

(57) ABSTRACT

A substrate processing method is provided and includes providing a substrate including an etching target film and a base film that is formed over the etching target film and includes a top surface and a side surface; exposing the substrate to a plasma generated from a film-forming gas containing a raw material gas containing carbon and hydrogen, thereby forming a first carbon film over the top surface of the base film selectively relative to the side surface of the base film; thermally processing the substrate to eliminate the hydrogen from the first carbon film; exposing the substrate to the plasma to form a second carbon film over the first carbon film; and etching the etching target film using, as masks, the base film, the first carbon film, and the second carbon film.

### CROSS-REFERENCE TO RELATED APPLICATIONS

This application is based upon and claims priority to Japanese Patent Application No. 2024-227743, filed on Dec. 24, 2024, the entire contents of which are incorporated herein by reference.

### BACKGROUND

### 1. Field of the Invention

The present disclosure relates to a substrate processing method, a substrate processing apparatus, and a substrate processing system.

### 2. Description of the Related Art

PCT Japanese Translation Patent Publication No. 2022-539699 discloses a technique of etching a base layer using a patterned carbon film as a mask, then forming an additional carbon film over the carbon film to form a thickened carbon film, and then additionally etching the base layer using the thickened carbon film as a mask.

### SUMMARY

A substrate processing method according to an aspect of the present disclosure includes: providing a substrate including an etching target film and a base film that is formed over the etching target film and includes a top surface and a side surface; exposing the substrate to a plasma generated from a film-forming gas containing a raw material gas containing carbon and hydrogen, thereby forming a first carbon film over the top surface of the base film selectively relative to the side surface of the base film; thermally processing the substrate to eliminate the hydrogen from the first carbon film; exposing the substrate to the plasma to form a second carbon film over the first carbon film; and etching the etching target film using, as masks, the base film, the first carbon film, and the second carbon film.

### BRIEF DESCRIPTION OF THE DRAWINGS

FIG. 1 is a flowchart illustrating a substrate processing method according to a first example of an embodiment of the present disclosure.

FIG. 2 is a cross-sectional diagram (1) illustrating the substrate processing method according to the first example of the embodiment.

FIG. 3 is a cross-sectional diagram (2) illustrating the substrate processing method according to the first example of the embodiment.

FIG. 4 is a cross-sectional diagram (3) illustrating the substrate processing method according to the first example of the embodiment.

FIG. 5 is a cross-sectional diagram (4) illustrating the substrate processing method according to the first example of the embodiment.

FIG. 6 is a cross-sectional diagram (5) illustrating the substrate processing method according to the first example of the embodiment.

FIG. 7 is a cross-sectional diagram (6) illustrating the substrate processing method according to the first example of the embodiment.

FIG. 8 is a diagram (1) illustrating a conventional substrate processing method.

FIG. 9 is a diagram (2) illustrating the conventional substrate processing method.

FIG. 10 is a diagram (3) illustrating the conventional substrate processing method.

FIG. 11 is a diagram (4) illustrating the conventional substrate processing method.

FIG. 12 is a diagram (5) illustrating the conventional substrate processing method.

FIG. 13 is a diagram (6) illustrating the conventional substrate processing method.

FIG. 14 is a flowchart illustrating a substrate processing method according to a second example of the embodiment.

FIG. 15 is a cross-sectional diagram (1) illustrating the substrate processing method according to the second example of the embodiment.

FIG. 16 is a cross-sectional diagram (2) illustrating the substrate processing method according to the second example of the embodiment.

FIG. 17 is a cross-sectional diagram (3) illustrating the substrate processing method according to the second example of the embodiment.

FIG. 18 is a cross-sectional diagram (4) illustrating the substrate processing method according to the second example of the embodiment.

FIG. 19 is a cross-sectional diagram (5) illustrating the substrate processing method according to the second example of the embodiment.

FIG. 20 is a cross-sectional diagram (6) illustrating the substrate processing method according to the second example of the embodiment.

FIG. 21 is a cross-sectional diagram (7) illustrating the substrate processing method according to the second example of the embodiment.

FIG. 22 is a cross-sectional diagram (8) illustrating the substrate processing method according to the second example of the embodiment.

FIG. 23 is a cross-sectional diagram (9) illustrating the substrate processing method according to the second example of the embodiment.

FIG. 24 is a cross-sectional diagram (10) illustrating the substrate processing method according to the second example of the embodiment.

FIG. 25 is a cross-sectional diagram (11) illustrating the substrate processing method according to the second example of the embodiment.

FIG. 26 is a cross-sectional diagram (12) illustrating the substrate processing method according to the second example of the embodiment.

FIG. 27 is a diagram illustrating a substrate processing system according to an embodiment of the present disclosure.

FIG. 28 is a schematic cross-sectional diagram illustrating a substrate processing apparatus according to an embodiment of the present disclosure.

FIG. 29 is a table illustrating results obtained by observing cross sections of carbon films.

FIG. 30 is a graph illustrating results obtained by measuring compositions of carbon films.

FIG. 31 is a graph illustrating results obtained by measuring densities of carbon films.

### DETAILED DESCRIPTION OF THE DISCLOSURE

The present disclosure provides a technique that can reduce defects in a root portion of a carbon film when forming the carbon film over a top surface of a patterned base film.

Hereinafter, non-limiting embodiments of the present disclosure will be described with reference to the drawings. In the drawings, the same or corresponding members or components are denoted by the same or corresponding reference signs, and duplicate description thereof will be omitted.

### [Substrate Processing Method]

### First Example

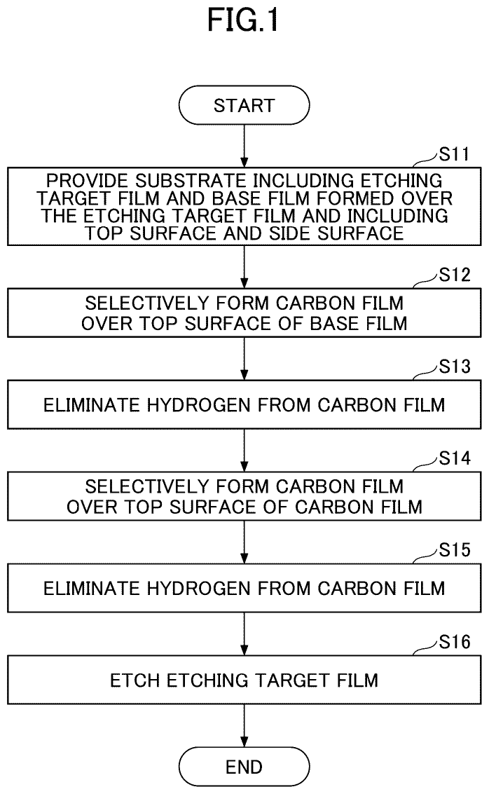

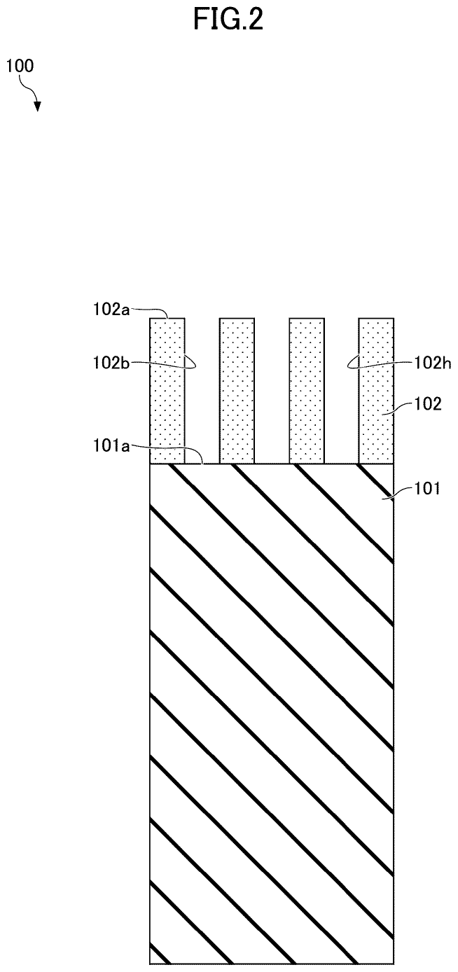

A substrate processing method according to a first example of an embodiment of the present disclosure will be described with reference to FIGS. 1 to 7. FIG. 1 is a flowchart illustrating the substrate processing method according to the first example of the embodiment. FIGS. 2 to 7 are cross-sectional diagrams illustrating the substrate processing method according to the first example of the embodiment. The substrate processing method according to the embodiment includes steps S11 to S16 illustrated in FIG. 1.

In step S11, a substrate 100 illustrated in FIG. 2 is provided. The substrate 100 includes an etching target film 101 and a base film 102. The etching target film 101 is, for example, a laminated film including silicon nitride films and silicon oxide films that are alternately laminated. The base film 102 is formed over the etching target film 101. The base film 102 is patterned. The base film 102 includes top surfaces 102a and side surfaces 102b. The base film 102 includes through holes 102h. The side surfaces 102b form an inner surface of each of the through holes 102h. The etching target film 101 includes exposed surfaces 101a. Each of the exposed surfaces 101a is exposed from the base film 102 through a corresponding one of the through holes 102h. The base film 102 is, for example, an amorphous carbon film.

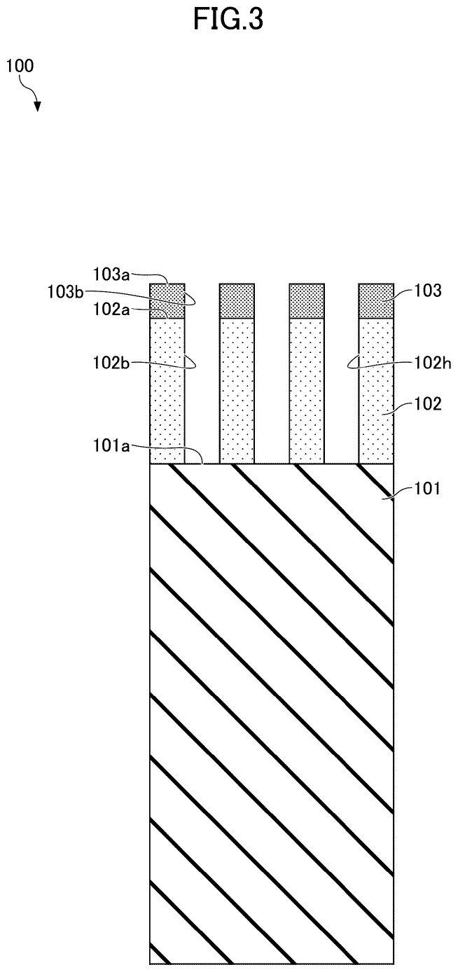

In step S12, as illustrated in FIG. 3, a carbon film 103 is formed over the top surfaces 102a of the base film 102 selectively relative to the side surfaces 102b of the base film 102. The carbon film 103 includes top surfaces 103a and side surfaces 103b. For example, RF power is supplied to generate a plasma from a film-forming gas containing a propylene gas, a helium gas, and a hydrogen gas, and the generated plasma is supplied to the substrate 100. This causes a film-forming reaction due to carbon-based film-forming species in the plasma and an etching reaction due to reactive hydrogen species in the plasma. Since the carbon-based film-forming species have a high adhesion coefficient, the carbon-based film-forming species tend to adhere to the top surfaces 102a rather than the side surfaces 102b. Since the reactive hydrogen species have a low adhesion coefficient, the reactive hydrogen species tend to reach and stay in the interior of the through holes 102h. Therefore, a film-forming reaction tends to occur on the top surfaces 102a, and an etching reaction tends to occur on the side surfaces 102b. As a result, the carbon film 103 can be formed over the top surfaces 102a of the base film 102 selectively relative to the side surfaces 102b of the base film 102. The film thickness of the carbon film 103 is, for example, 100 nanometers (nm) or greater and 200 nm or less. In this case, a period for exposure of the carbon film 103 to the film-forming gas is reduced, and thus etching of the carbon film 103 due to the reactive hydrogen species in the plasma, generated from the film-forming gas, is easily prevented. A propylene gas is an example of the raw material gas containing carbon and hydrogen. The raw material gas may be a hydrocarbon gas other than the propylene gas, e.g., an ethylene gas or an acetylene gas. A helium gas is an example of an inert gas. The inert gas may be a noble gas other than the helium gas, e.g., an argon gas, a neon gas, or a krypton gas. The inert gas may be a nitrogen gas. An example of conditions for step S12 is as follows.

### Conditions for Step S12

Propylene gas: 10 sccm or more and 50 sccm or less
Helium gas: 300 sccm or more and 1,000 sccm or less
Hydrogen gas: 5 sccm or more and 50 sccm or less
Pressure: 0.3 Torr or higher and 2 Torr or lower
RF power: 300 W or higher and 1,000 W or lower (40 MHz or higher)
Substrate temperature (first temperature): 200° C. or higher and 400° C. or lower

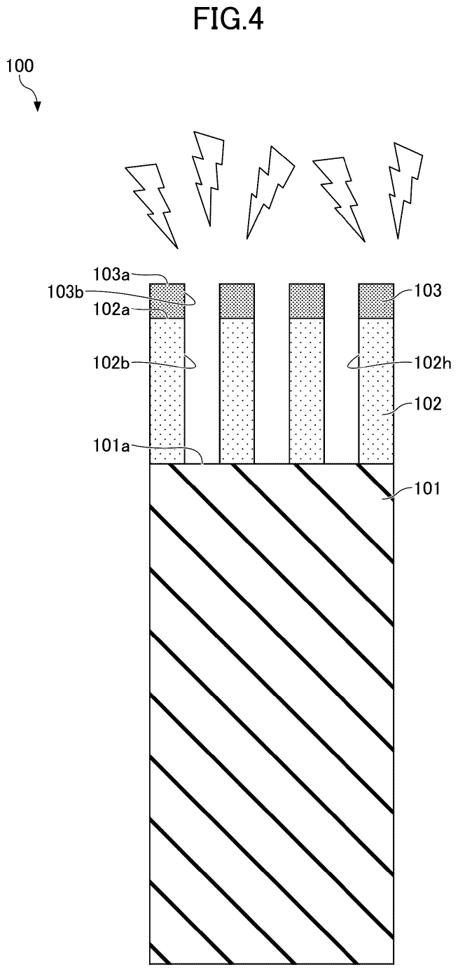

In step S13, as illustrated in FIG. 4, the substrate 100 is thermally processed to eliminate hydrogen from the carbon film 103. Thus, the carbon film 103 is densified to have enhanced etching resistance to the reactive hydrogen species and the like. The thermal processing of the substrate 100 may be performed in an atmosphere of an inert gas. In this case, it is possible to prevent oxidation of the carbon film 103. The inert gas is, for example, a noble gas (e.g., a helium gas, an argon gas, a neon gas, a krypton gas, or the like) or a nitrogen gas. The substrate temperature at which hydrogen is eliminated from the carbon film 103 may be higher than the substrate temperature at which the carbon film 103 is formed. In this case, hydrogen is easily eliminated from the carbon film 103. An example of conditions for step S13 is as follows.

### Conditions for Step S13

Argon gas: 100 sccm or more and 5,000 sccm or less
Pressure: 0.1 Torr or higher and 5 Torr or lower
Substrate temperature: 400° C. or higher and 800° C. or lower
Period: 5 minutes or greater and 60 minutes or less

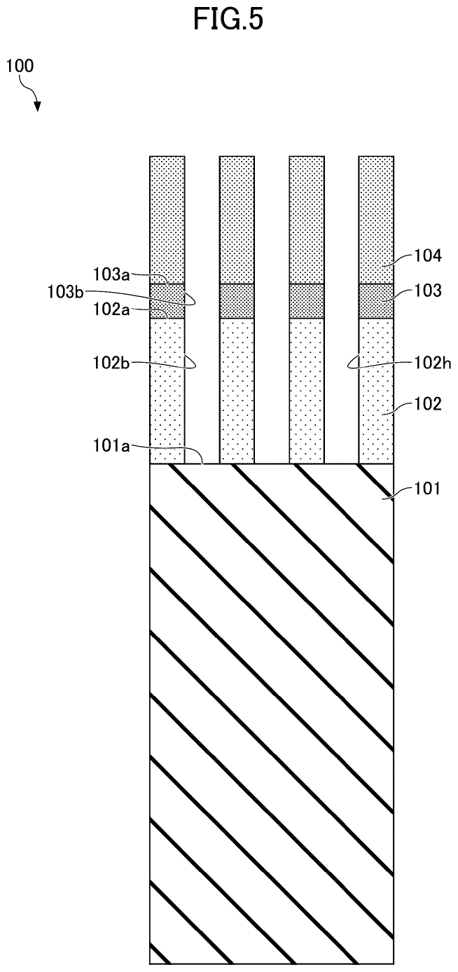

In step S14, as illustrated in FIG. 5, a carbon film 104 is formed over the top surfaces 103a of the carbon film 103 selectively relative to the side surfaces 103b of the carbon film 103. The carbon film 104 can be formed, for example, in the same manner as that used for forming the carbon film 103. In step S14, the carbon film 103 is exposed to the plasma generated from the film-forming gas. Therefore, it is considered that the carbon film 103 would be etched by the reactive hydrogen species in the plasma. However, the carbon film 103, from which hydrogen was eliminated, has high etching resistance to the reactive hydrogen species and the like. Therefore, even if the carbon film 103 is exposed to the plasma generated from the film-forming gas, an etching reaction due to the reactive hydrogen species in the plasma is unlikely to occur. As a result, the carbon film 104 can be formed over the top surfaces 103a of the carbon film 103 selectively relative to the side surfaces 103b of the carbon film 103 without etching the carbon film 103. The film thickness of the carbon film 104 may be greater than the film thickness of the carbon film 103. The film thickness of the carbon film 104 is, for example, 200 nm or greater and 400 nm or less.

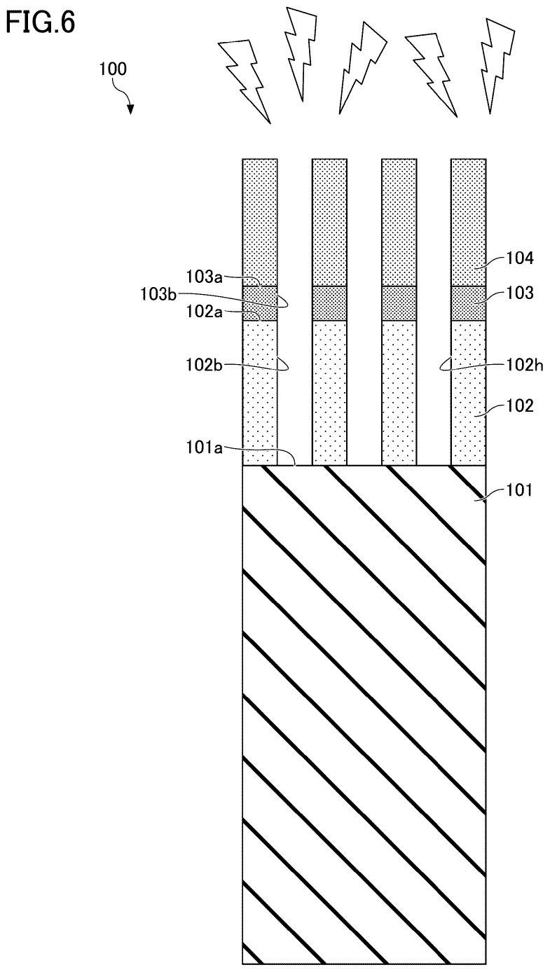

In step S15, as illustrated in FIG. 6, the substrate 100 is thermally processed to eliminate hydrogen from the carbon film 104. As a result, the carbon film 104 is densified to have enhanced etching resistance to the reactive hydrogen species and the like. Conditions for the thermal processing in step S15 may be the same as the conditions for the thermal processing in step S13. Step S15 may be omitted. This is because the carbon film 104 is not exposed to the plasma (reactive hydrogen species) of the film-forming gas after step S15. However, step S15 is preferably performed from the viewpoint of enhancing etching resistance to an etching gas used in step S16, which will be described below.

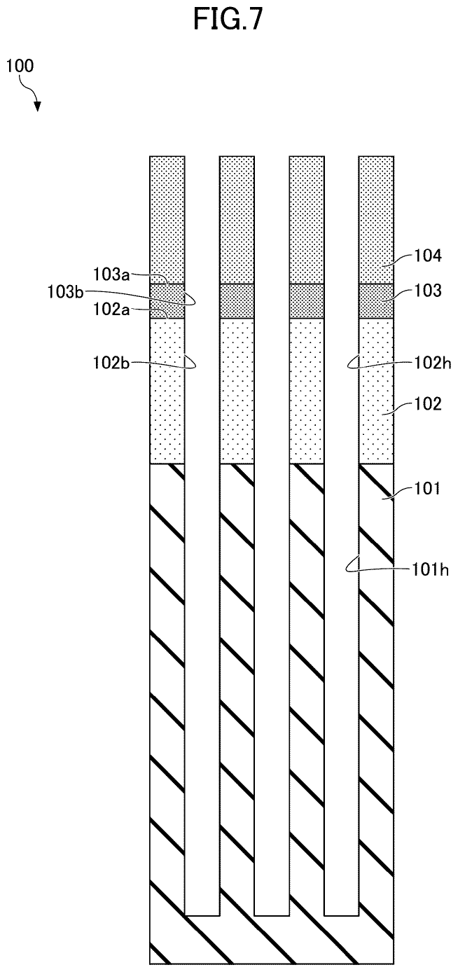

In step S16, as illustrated in FIG. 7, the etching target film 101 is etched using, as masks, the base film 102, the carbon film 103, and the carbon film 104. Thus, holes 101h are formed in the etching target film 101. For example, an etching gas that can etch the etching target film 101 selectively relative to the base film 102, the carbon film 103, and the carbon film 104 is supplied to the substrate 100. Thus, the etching target film 101 can be etched to form the holes 101h. For example, when the etching target film 101 is a laminated film including silicon nitride films and silicon oxide films alternately laminated, for example, a gas containing fluorine and carbon (e.g., CₓF_{y} or CₓF_{y}H_{z}, where each of x, y, and z is an integer of 1 or greater) can be used as the etching gas. The plasma may be generated from the etching gas.

Thus, the holes 101h can be formed in the etching target film 101.

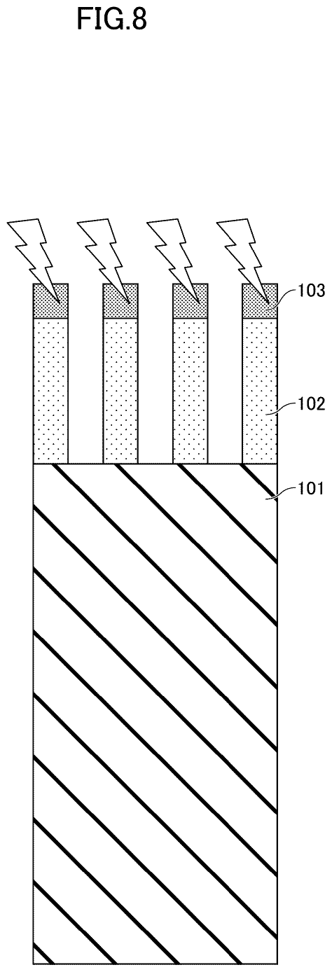

Next, a conventional substrate processing method will be described with reference to FIGS. 8 to 13. FIGS. 8 to 13 are diagrams illustrating the conventional substrate processing method.

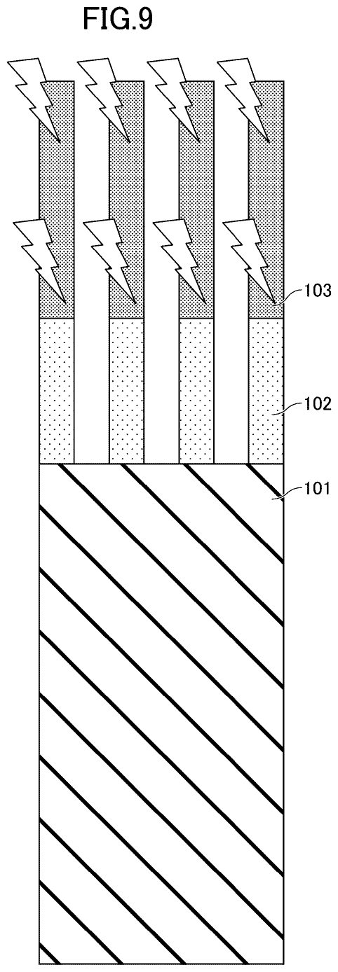

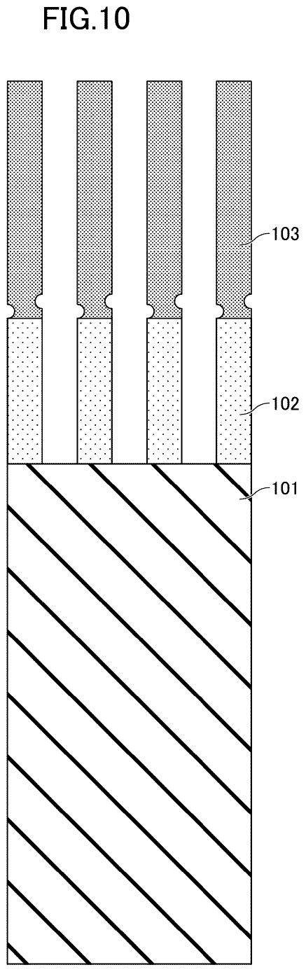

Forming the carbon film 103 by supply, to the substrate 100, of a plasma generated from a film-forming gas containing a raw material gas containing carbon and hydrogen causes a film-forming reaction due to the carbon-based film forming species in the plasma and an etching reaction due to the reactive hydrogen species in the plasma. The carbon-based film forming species have a high adhesion coefficient, and the reactive hydrogen species have a low adhesion coefficient. Therefore, when the carbon film 103 having a large film thickness is to be formed, the carbon film 103 formed in an initial stage of the film formation is exposed to the reactive hydrogen species in the initial stage of the film formation as illustrated in FIG. 8, and is continuously exposed to the reactive hydrogen species during the film formation as illustrated in FIG. 9. In other words, when the carbon film 103 having a large film thickness is to be formed, the carbon film 103 formed in the initial stage of the film formation is exposed to the reactive hydrogen species over a long period of time. Therefore, the carbon film 103 formed in the initial stage of the film formation is more likely to be etched. As a result, as illustrated in FIG. 10, a root portion of the carbon film 103 formed in the initial stage of the film formation may be thin. The large film thickness is, for example, 300 nm or greater and 1 micrometer (μm) or less.

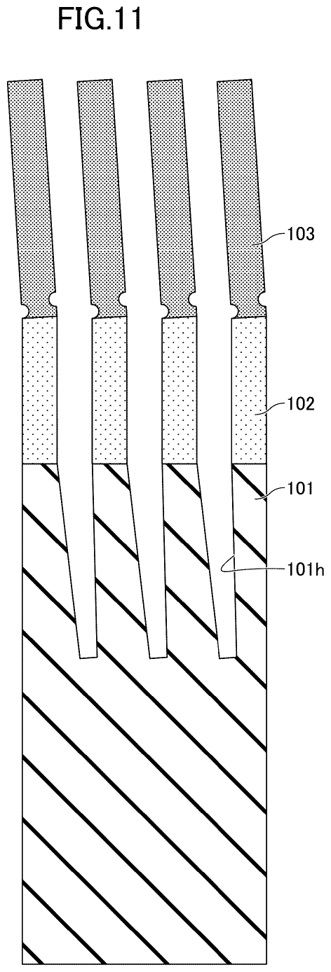

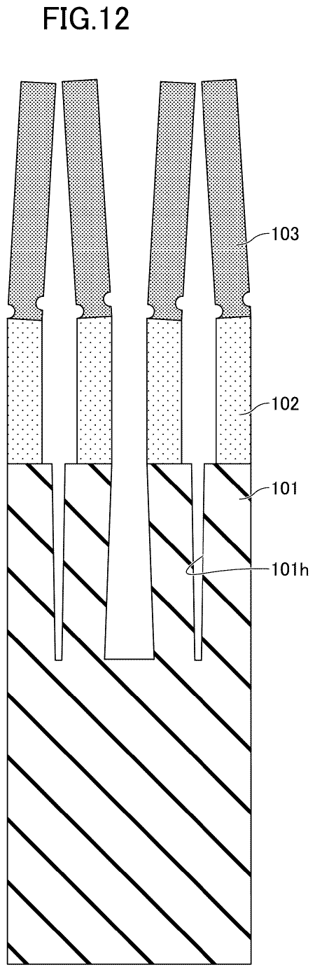

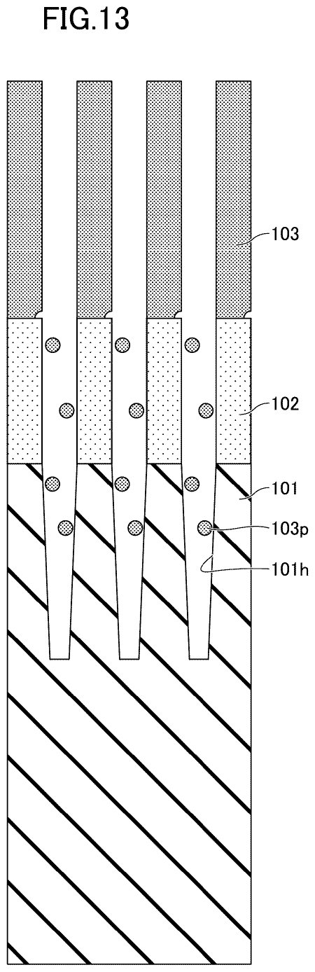

When the etching target film 101 is etched using, as a mask, the carbon film 103 having a thinned root portion, the carbon film 103 becomes tilted, as illustrated in FIG. 11, resulting in poor etching straightness of the etching target film 101. Also, as illustrated in FIG. 12, the carbon film 103 collapses, resulting in a decreased or increased opening diameter of the holes 101h formed in the etching target film 101. Also, the root portion of the carbon film 103 is fragile, and thus crumbles apart during etching, resulting in the formation of particles 103p, as illustrated in FIG. 13.

According to the substrate processing method according to the first example of the embodiment, first, in step S12, the carbon film 103 is formed over the top surfaces 102a of the base film 102 selectively relative to the side surfaces 102b of the base film 102. Next, in step S13, the substrate 100 is thermally processed to eliminate hydrogen from the carbon film 103. Next, in step S14, the carbon film 104 is formed over the top surfaces 103a of the carbon film 103 selectively relative to the side surfaces 103b of the carbon film 103. Next, in step S16, the etching target film 101 is etched using, as masks, the base film, the carbon film 103, and the carbon film 104. The carbon film 103, from which hydrogen was eliminated in step S13, has high etching resistance to the reactive hydrogen species and the like. Thus, even if the carbon film 103 is exposed to the plasma generated from the film-forming gas in step S14, an etching reaction due to the reactive hydrogen species in the plasma is unlikely to occur. As a result, the carbon film 104 can be formed over the top surfaces 103a of the carbon film 103 selectively relative to the side surfaces 103b of the carbon film 103 without etching the carbon film 103. In other words, when the carbon films (the carbon film 103 and the carbon film 104) are to be formed over the top surfaces of the patterned base film 102, it is possible to reduce defects in the root portions of the carbon films (the carbon film 103 and the carbon film 104).

### Second Example

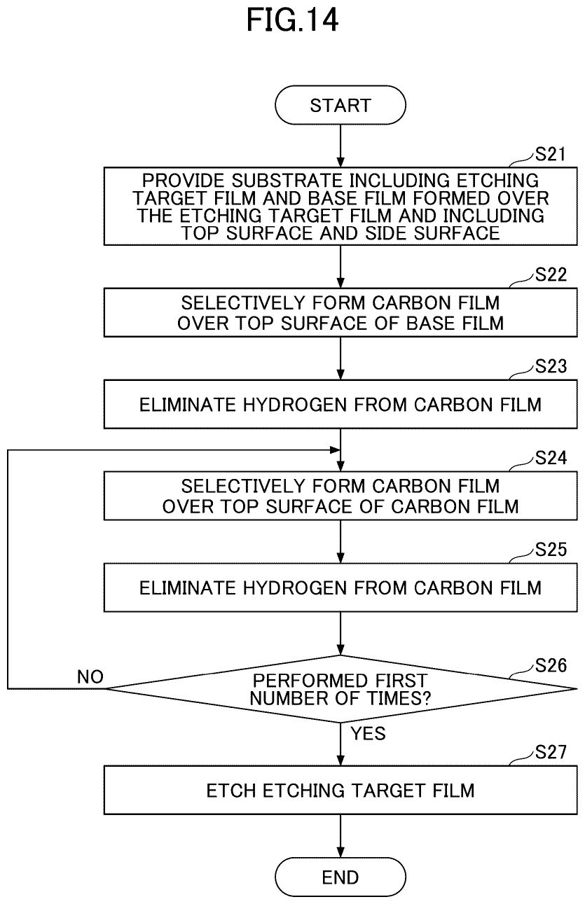

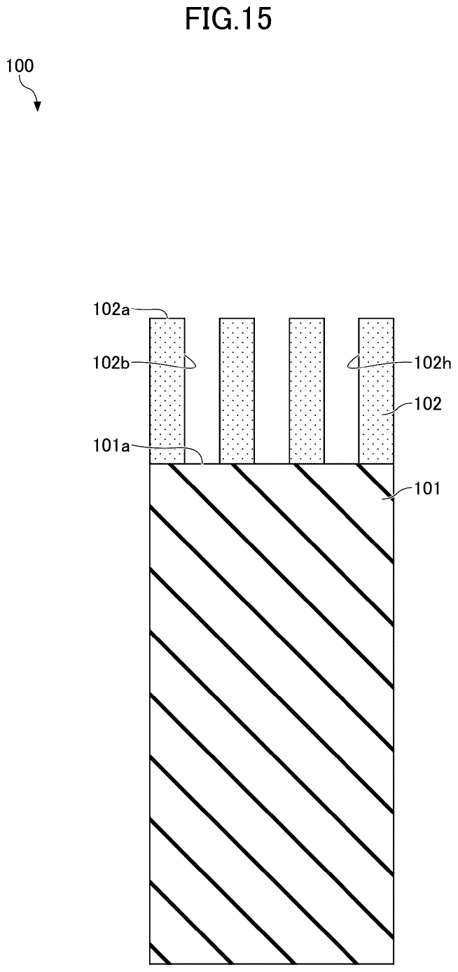

A substrate processing method according to a second example of the embodiment will be described with reference to FIGS. 14 to 26. FIG. 14 is a flowchart illustrating the substrate processing method according to the second example of the embodiment. FIGS. 15 to 26 are cross-sectional diagrams illustrating the substrate processing method according to the second example of the embodiment.

The substrate processing method according to the second example of the embodiment is different from the substrate processing method according to the first example of the embodiment in that the etching target film 101 is etched after the formation of the carbon film 104 and the elimination of hydrogen from the carbon film 104 are performed a first number of times. In the following, the first number of times is two times or more. The following description will be made based on an example in which the first number of times is four. The substrate processing method according to the second example of the embodiment includes steps S21 to S27 illustrated in FIG. 14.

In step S21, the substrate 100 illustrated in FIG. 15 is provided. Step S21 may be the same as step S11.

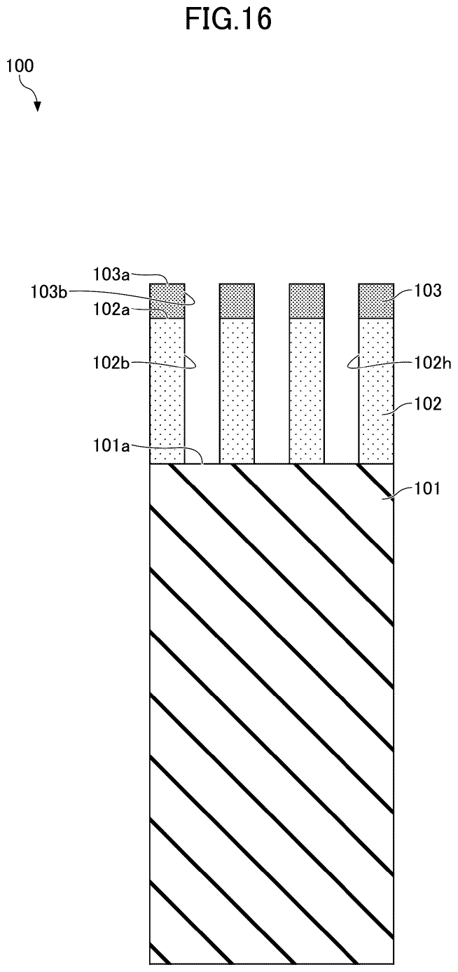

In step S22, as illustrated in FIG. 16, the carbon film 103 is formed over the top surfaces 102a of the base film 102 selectively relative to the side surfaces 102b of the base film 102. Step S22 may be the same as step S12.

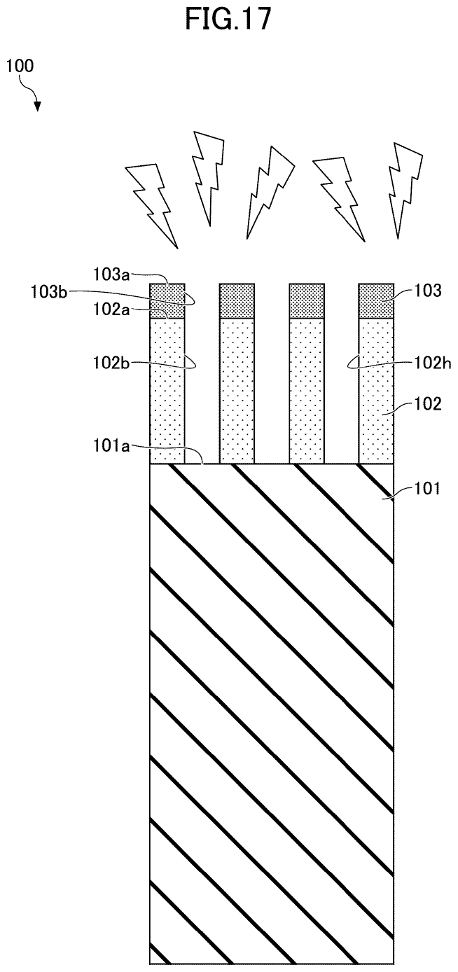

In step S23, as illustrated in FIG. 17, the substrate 100 is thermally processed to eliminate hydrogen from the carbon film 103. Step S23 may be the same as step S13.

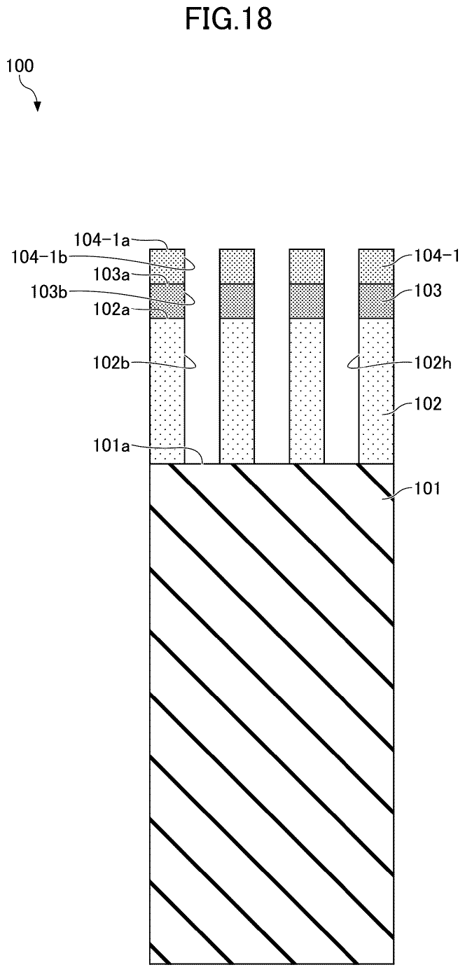

In step S24, as illustrated in FIG. 18, a carbon film 104-1 is formed over the top surfaces 103a of the carbon film 103 selectively relative to the side surfaces 103b of the carbon film 103. The carbon film 104-1 includes top surfaces 104-1a and side surfaces 104-1b. The carbon film 104-1 can be formed, for example, in the same manner as that used for forming the carbon film 103. In step S24, the carbon film 103 is exposed to the plasma generated from the film-forming gas. Therefore, it is considered that the carbon film 103 would be etched by the reactive hydrogen species in the plasma. However, the carbon film 103, from which hydrogen was eliminated, has high etching resistance to the reactive hydrogen species and the like. Therefore, even if the carbon film 103 is exposed to the plasma generated from the film-forming gas, an etching reaction due to the reactive hydrogen species in the plasma is unlikely to occur. As a result, the carbon film 104-1 can be formed over the top surfaces 103a of the carbon film 103 selectively relative to the side surfaces 103b of the carbon film 103 without etching the carbon film 103. The film thickness of the carbon film 104-1 may be equal to the film thickness of the carbon film 103. The film thickness of the carbon film 104-1 is, for example, 100 nm or greater and 200 nm or less. In this case, a period for exposure of the carbon film 104-1 to the film-forming gas is reduced, and thus etching of the carbon film 104-1 due to the reactive hydrogen species in the plasma, generated from the film-forming gas, is easily prevented.

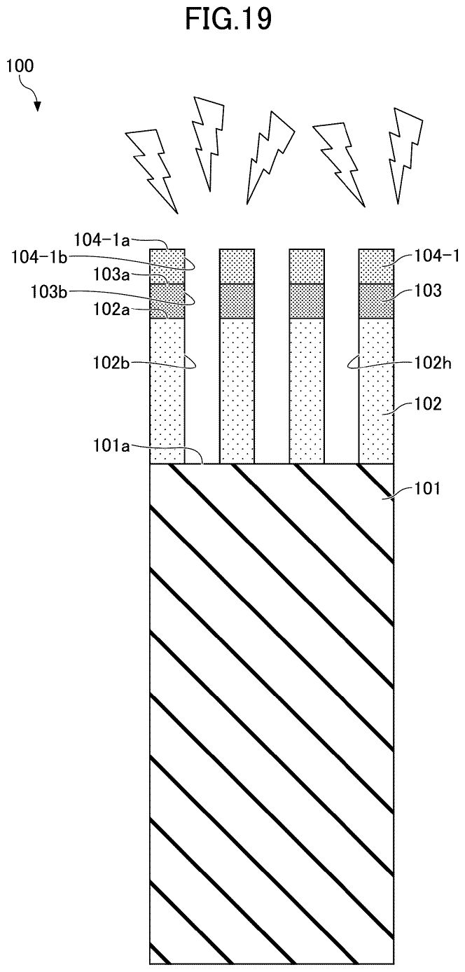

In step S25, as illustrated in FIG. 19, the substrate 100 is thermally processed to eliminate hydrogen from the carbon film 104-1. Thus, the carbon film 104-1 is densified to have enhanced etching resistance to the reactive hydrogen species and the like. Conditions for the thermal processing in step S25 may be the same as the conditions for the thermal processing in step S23.

In step S26, it is determined whether or not a process of steps S24 and S25 has been performed the first number of times. In this example, the first number of times is four. The number of times of the process of steps S24 and S25 that was performed is one, and has not yet reached four. Therefore, the process returns to step S24 to perform the process of steps S24 and S25.

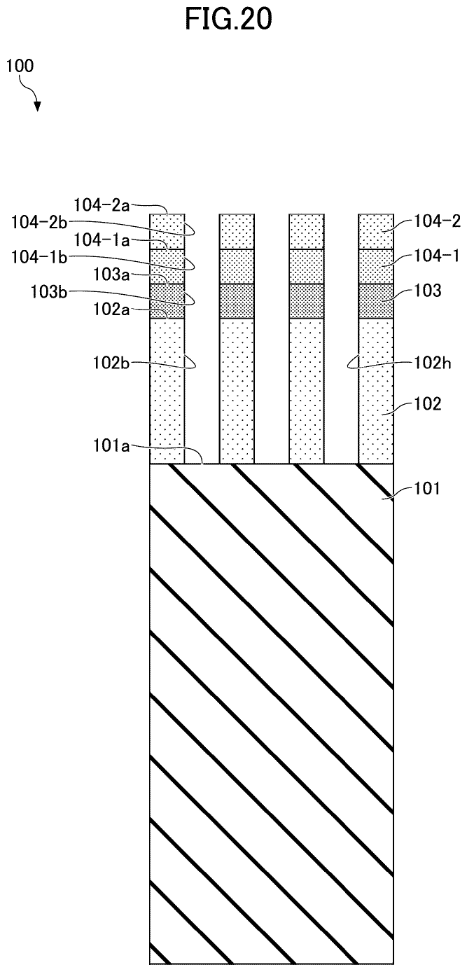

In step S24 in the second time, as illustrated in FIG. 20, a carbon film 104-2 is formed over the top surfaces 104-1a of the carbon film 104-1 selectively relative to the side surfaces 104-1b of the carbon film 104-1. The carbon film 104-2 can be formed, for example, in the same manner as that used for forming the carbon film 103. In step S24 in the second time, the carbon film 103 and the carbon film 104-1 are exposed to the plasma generated from the film-forming gas. Therefore, it is considered that the carbon film 103 and the carbon film 104-1 would be etched by the reactive hydrogen species in the plasma. However, the carbon film 103 and the carbon film 104-1, from which hydrogen was eliminated, have high etching resistance to the reactive hydrogen species and the like. Therefore, even if the carbon film 103 and the carbon film 104-1 are exposed to the plasma generated from the film-forming gas, an etching reaction due to the reactive hydrogen species in the plasma is unlikely to occur. As a result, the carbon film 104-2 can be formed over the top surfaces 104-1a of the carbon film 104 selectively relative to the side surfaces 104-1b of the carbon film 104 without etching the carbon film 103 and the carbon film 104-1. The film thickness of the carbon film 104-2 may be equal to the film thickness of the carbon film 103. The film thickness of the carbon film 104-2 is, for example, 100 nm or greater and 200 nm or less. In this case, a period for exposure of the carbon film 104-2 to the film-forming gas is reduced, and thus etching of the carbon film 104-2 due to the reactive hydrogen species in the plasma, generated from the film-forming gas, is easily prevented.

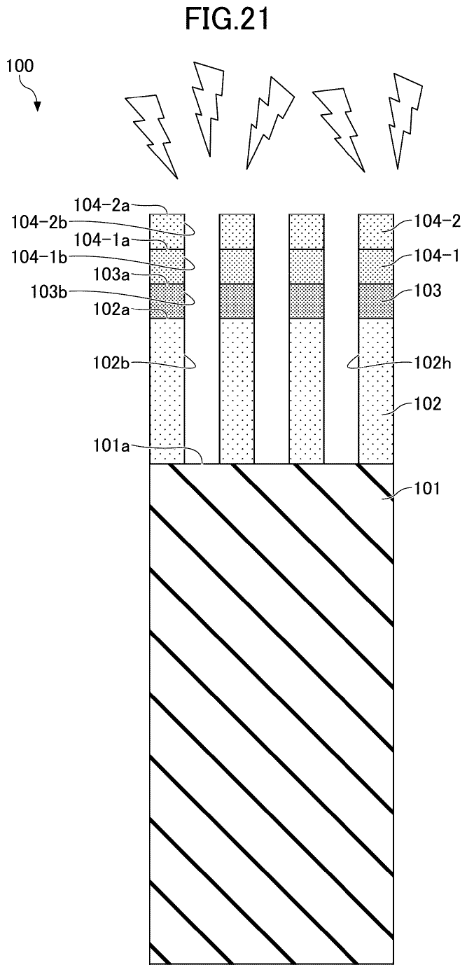

In step S25 in the second time, as illustrated in FIG. 21, the substrate 100 is thermally processed to eliminate hydrogen from the carbon film 104-2. Thus, the carbon film 104-2 is densified to have enhanced etching resistance to the reactive hydrogen species and the like. Conditions for the thermal processing in step S25 in the second time may be the same as the conditions for the thermal processing in step S23.

In step S26 in the second time, it is determined whether or not the process of steps S24 and S25 has been performed the first number of times. In this example, the first number of times is four. The number of times of the process of steps S24 and S25 that was performed is two, and has not yet reached four. Therefore, the process returns to step S24 to perform the process of steps S24 and S25.

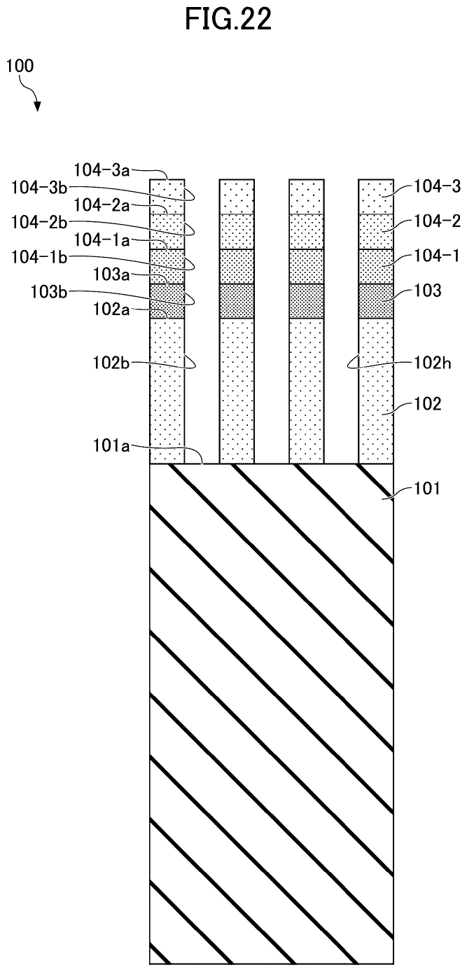

In step S24 in the third time, as illustrated in FIG. 22, a carbon film 104-3 is formed over top surfaces 104-2a of the carbon film 104-2 selectively relative to side surfaces 104-2b of the carbon film 104-2. The carbon film 104-3 can be formed, for example, in the same manner as that used for forming the carbon film 103. In step S24 in the third time, the carbon film 103, the carbon film 104-1, and the carbon film 104-2 are exposed to the plasma generated from the film-forming gas. Therefore, it is considered that the carbon film 103, the carbon film 104-1, and the carbon film 104-2 would be etched by the reactive hydrogen species in the plasma. However, the carbon film 103, the carbon film 104-1, and the carbon film 104-2, from which hydrogen was eliminated, have high etching resistance to the reactive hydrogen species and the like. Therefore, even if the carbon film 103, the carbon film 104-1, and the carbon film 104-2 are exposed to the plasma generated from the film-forming gas, an etching reaction due to the reactive hydrogen species in the plasma is unlikely to occur. As a result, the carbon film 104-3 can be formed over the top surfaces 104-2a of the carbon film 104 selectively relative to the side surfaces 104-2b of the carbon film 104 without etching the carbon film 103, the carbon film 104-1, and the carbon film 104-2. The film thickness of the carbon film 104-3 may be equal to the film thickness of the carbon film 103. The film thickness of the carbon film 104-3 is, for example, 100 nm or greater and 200 nm or less. In this case, a period for exposure of the carbon film 104-3 to the film-forming gas is reduced, and thus etching of the carbon film 104-3 due to the reactive hydrogen species in the plasma, generated from the film-forming gas, is easily prevented.

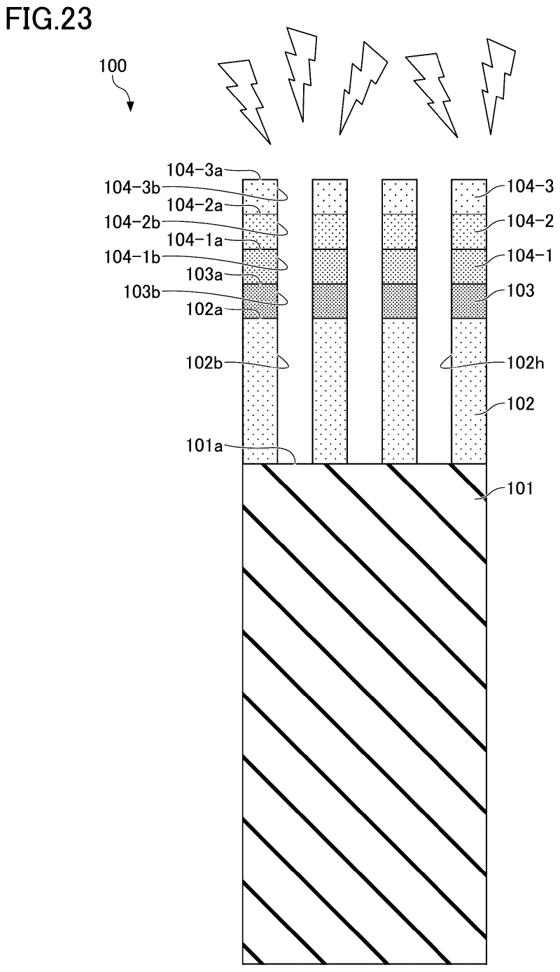

In step S25 in the third time, as illustrated in FIG. 23, the substrate 100 is thermally processed to eliminate hydrogen from the carbon film 104-3. Thus, the carbon film 104-3 is densified to have enhanced etching resistance to the reactive hydrogen species and the like. Conditions for the thermal processing in step S25 in the third time may be the same as the conditions for the thermal processing in step S23.

In step S26 in the third time, it is determined whether or not the process of steps S24 and S25 has been performed the first number of times. In this example, the first number of times is four. The number of times of the process of steps S24 and S25 that was performed is three, and has not yet reached four. Therefore, the process returns to step S24 to perform the process of steps S24 and S25.

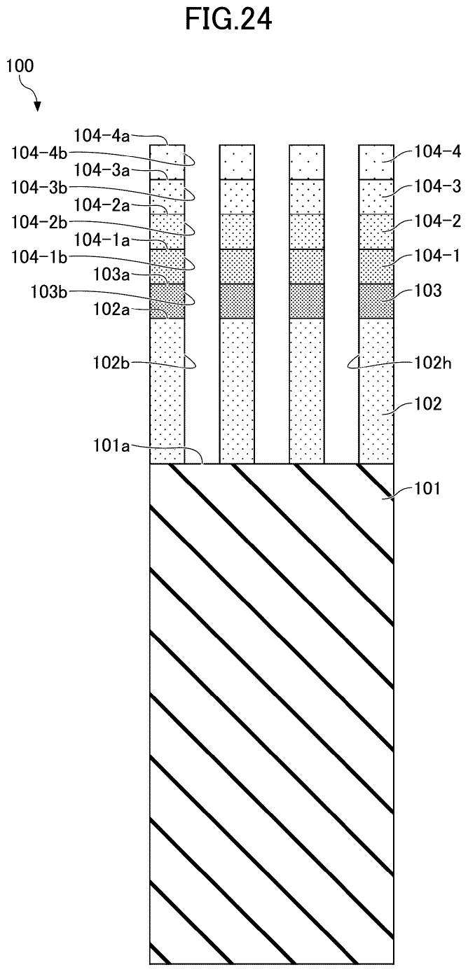

In step S24 in the fourth time, as illustrated in FIG. 24, a carbon film 104-4 is formed over top surfaces 104-3a of the carbon film 104-3 selectively relative to side surfaces 104-3b of the carbon film 104-3. The carbon film 104-4 can be formed, for example, in the same manner as that used for forming the carbon film 103. In step S24 in the fourth time, the carbon film 103, the carbon film 104-1, the carbon film 104-2, and the carbon film 104-3 are exposed to the plasma generated from the film-forming gas. Therefore, it is considered that the carbon film 103, the carbon film 104-1, the carbon film 104-2, and the carbon film 104-3 would be etched by the reactive hydrogen species in the plasma. However, the carbon film 103, the carbon film 104-1, the carbon film 104-2, and the carbon film 104-3, from which hydrogen was eliminated, have high etching resistance to the reactive hydrogen species and the like. Therefore, even if the carbon film 103, the carbon film 104-1, the carbon film 104-2, and the carbon film 104-3 are exposed to the plasma generated from the film-forming gas, an etching reaction due to the reactive hydrogen species in the plasma is unlikely to occur. As a result, the carbon film 104-4 can be formed over the top surfaces 104-3a of the carbon film 104 selectively relative to the side surfaces 104-3b of the carbon film 104 without etching the carbon film 103, the carbon film 104-1, the carbon film 104-2, and the carbon film 104-3. The film thickness of the carbon film 104-4 may be equal to the film thickness of the carbon film 103. The film thickness of the carbon film 104-4 is, for example, 100 nm or greater and 200 nm or less. In this case, a period for exposure of the carbon film 104-4 to the film-forming gas is reduced, and thus etching of the carbon film 104-4 due to the reactive hydrogen species in the plasma, generated from the film-forming gas, is easily prevented.

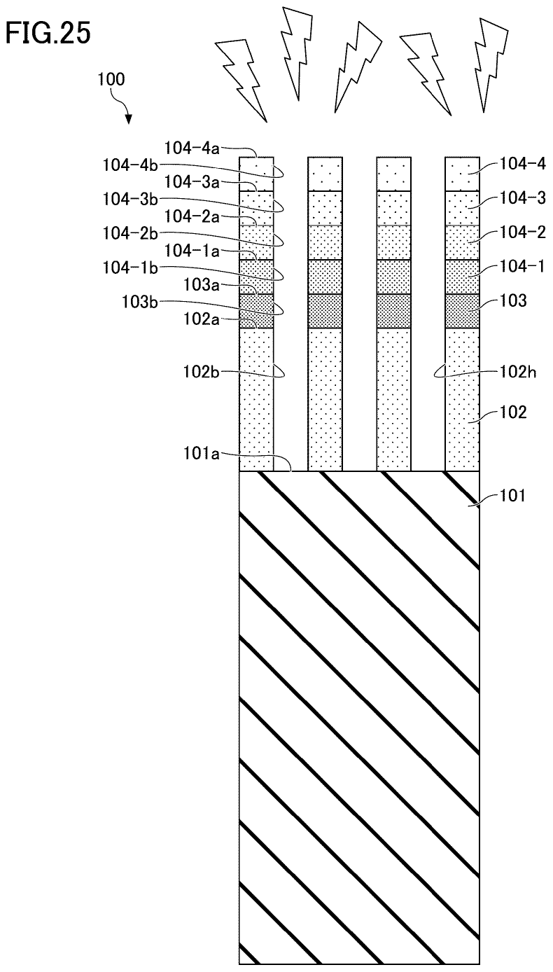

In step S25 in the fourth time, as illustrated in FIG. 25, the substrate 100 is thermally processed to eliminate hydrogen from the carbon film 104-4. Thus, the carbon film 104-4 is densified to have enhanced etching resistance to the reactive hydrogen species and the like. Conditions for the thermal processing in step S25 in the fourth time may be the same as the conditions for the thermal processing in step S23.

In step S26 in the fourth time, it is determined whether or not the process of steps S24 and S25 has been performed the first number of times. In this example, the first number of times is four. The number of times of the process of steps S24 and S25 that was performed is four, i.e., the first number of times. Therefore, the process proceeds to step S27.

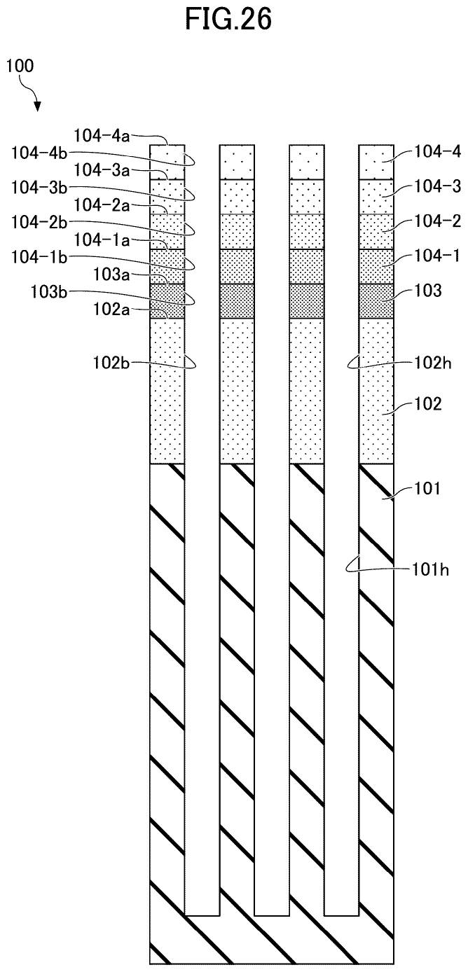

In step S27, as illustrated in FIG. 26, the etching target film 101 is etched using, as masks, the base film 102, the carbon film 103, the carbon film 104-1, the carbon film 104-2, the carbon film 104-3, and the carbon film 104-4. Thus, the holes 101h are formed in the etching target film 101. For example, an etching gas that can etch the etching target film 101 selectively relative to the base film 102, the carbon film 103, the carbon film 104-1, the carbon film 104-2, the carbon film 104-3, and the carbon film 104-4 is supplied to the substrate 100. Thus, the etching target film 101 can be etched to form the holes 101h. For example, when the etching target film 101 is a laminated film including silicon nitride films and silicon oxide films alternately laminated, a gas containing fluorine and carbon (e.g., CₓF_{y} or CₓF_{y}H_{z}, where each of x, y, and z is an integer of 1 or greater) can be used as the etching gas. The plasma may be generated from the etching gas.

In this manner, the holes 101h can be formed in the etching target film 101.

According to the substrate processing method according to the second example of the embodiment, it is possible to obtain the same effects as those of the substrate processing method according to the first example of the embodiment. That is, when the carbon films (the carbon films 103 and 104) are formed over the top surfaces of the patterned base film 102, it is possible to reduce defects in the root portions of the carbon films (the carbon films 103 and 104).

### [Substrate Processing System]

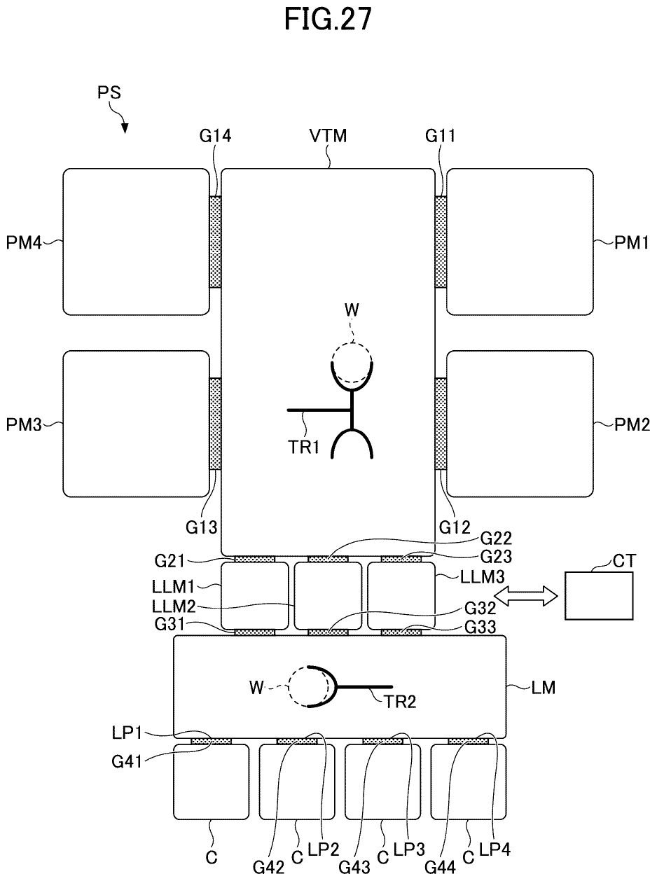

A substrate processing system PS according to an embodiment of the present disclosure will be described with reference to FIG. 27. FIG. 27 is a diagram illustrating the substrate processing system PS according to the embodiment. In the following description, the substrate processing system PS includes four processing chambers. However, the number of processing chambers is not limited to four. The number of load lock chambers and the number of load ports are not limited to the numbers illustrated in FIG. 27.

The substrate processing system PS includes processors PM1 to PM4 (examples of first to fourth processors), a vacuum transfer chamber VTM, load lock chambers LLM1 to LLM3, an atmospheric transfer chamber LM, load ports LP1 to LP4, and a controller CT.

The processors PM1 to PM4 are connected to the vacuum transfer chamber VTM via gate valves G11 to G14. The interior of the processors PM1 to PM4 is reduced in pressure to a predetermined vacuum atmosphere, and desired processing is performed on the substrate W in the interior of the processors PM1 to PM4. The substrate W is, for example, the substrate 100 described above.

The processor PM1 is configured, for example, to perform processing for forming the carbon film 103 over the substrate W (step S12 in FIG. 1).

The processor PM2 is configured, for example, to perform processing for eliminating hydrogen from the carbon film 103 (step S13 in FIG. 1).

The processor PM3 is configured, for example, to perform processing for forming the carbon film 104 over the top surfaces 103a of the carbon film 103 selectively relative to the side surfaces 103b of the carbon film 103 (step S14 in FIG. 1).

The processor PM4 is configured, for example, to perform processing for eliminating hydrogen from the carbon film 104 (step S15 in FIG. 1).

The vacuum transfer chamber VTM is reduced in pressure to a predetermined vacuum atmosphere. The vacuum transfer chamber VIM is provided with a transfer mechanism TR1 configured to transfer the substrate W under reduced pressure. The transfer mechanism TR1 transfers the substrate W to the processors PM1 to PM4 and the load lock chambers LLM1 to LLM3. The transfer mechanism TR1 includes, for example, two transfer arms. However, the transfer mechanism TR1 may include a single arm.

The load lock chambers LLM1 to LLM3 are connected to the vacuum transfer chamber VIM via gate valves G21 to G23, and are connected to the atmospheric transfer chamber LM via gate valves G31 to G33. The load lock chambers LLM1 to LLM3 are switched between an atmospheric atmosphere and a vacuum atmosphere.

The interior of the atmospheric transfer chamber LM is an atmospheric atmosphere and, for example, a downflow of clean air is formed. An aligner (not shown) configured to align the substrate W is provided in the interior of the atmospheric transfer chamber LM. A transfer mechanism TR2 is provided in the atmospheric transfer chamber LM. The transfer mechanism TR2 includes, for example, a single transfer arm. However, the transfer mechanism TR2 may include two or more transfer arms. The transfer mechanism TR2 is configured to transfer the substrate W to the load lock chambers LLM1 to LLM3, carriers C of the load ports LP1 to LP4, and the aligner.

The load ports LP1 to LP4 are provided in the longitudinal side wall of the atmospheric transfer chamber LM. The carriers C with or without the substrate W are attached to the load ports LP1 to LP4 via gate valves G41 to G44. The carrier C is, for example, a FOUP (Front Opening Unified Pod).

The controller CT is configured to control each component of the substrate processing system PS. For example, the controller CT executes operations of the processors PM1 to PM4, operations of the transfer mechanisms TR1 and TR2, opening and closing of the gate valves G11 to G14, G21 to G23, G31 to G33, and G41 to G44, and switching of the atmosphere in the load lock chambers LLM1 to LLM3.

The substrate processing system PS includes a plurality of processing chambers (the processors PM1 to PM4), a vacuum transfer chamber (the vacuum transfer chamber VTM) configured to vacuum-transfer the substrate W between the processing chambers, and the controller CT. The controller CT controls the processing performed by each of the processors PM1 to PM4. With this configuration, the processing can be performed on the substrate W in each of the processing chambers without exposing the substrate W to the atmosphere, i.e., without breaking the vacuum state.

The etching of the etching target film 101 (step S16 in FIG. 1) may be performed by at least one of the processors PM1 to PM4, or may be performed by a device that is not included in the substrate processing system PS.

Also, two or more of the formation of the carbon film 103, the elimination of hydrogen from the carbon film 103, the formation of the carbon film 104, and the elimination of hydrogen from the carbon film 104 may be performed by the single processor. All of the formation of the carbon film 103, the elimination of hydrogen from the carbon film 103, the formation of the carbon film 104, and the elimination of hydrogen from the carbon film 104 may be performed by the single processor.

Also, steps S22, S23, S24, S25, and S27 of FIG. 14 may be performed by different processors, or two or more of these steps may be performed by the single processor.

### [Substrate Processing Apparatus]

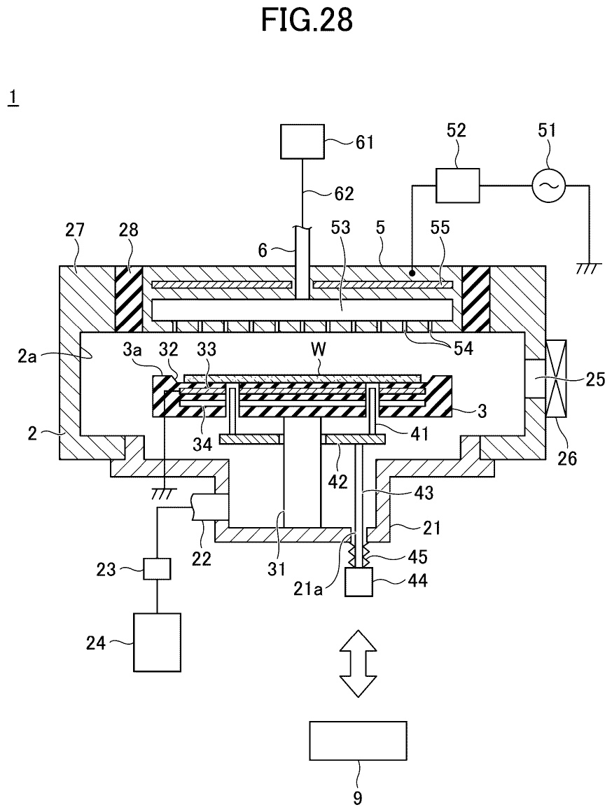

A substrate processing apparatus 1 applicable as the processor PM1 provided in the substrate processing system PS will be described with reference to FIG. 28. The processors PM2, PM3, and PM4 may have the same configuration as the configuration of the processor PM1. FIG. 28 is a schematic cross-sectional diagram illustrating the substrate processing apparatus 1 according to an embodiment of the present disclosure.

The substrate processing apparatus 1 includes a substantially cylindrical airtight processing chamber 2. A gas exhaust chamber 21 is provided at a center portion of the bottom wall of the processing chamber 2.

The gas exhaust chamber 21 has, for example, a substantially cylindrical shape that projects downward. A gas exhaust flow path 22 is connected to the gas exhaust chamber 21, for example, at a side surface of the gas exhaust chamber 21.

A gas exhauster 24 is connected to the gas exhaust flow path 22 via a pressure adjuster 23. The pressure adjuster 23 includes, for example, a pressure adjusting valve, such as a butterfly valve or the like. The gas exhauster 24 includes, for example, a vacuum pump. The gas exhaust flow path 22 is configured to reduce the internal pressure of the processing chamber 2 by the gas exhauster 24. A transfer port 25 is provided in a side surface of the processing chamber 2. The transfer port 25 is configured to be open and closed by a gate valve 26. Transfer of the substrate W between the processing chamber 2 and a transfer chamber (not shown) is performed through the transfer port 25.

A stage 3 configured to hold the substrate W substantially horizontally is provided in the processing chamber 2. The stage 3 is formed in a substantially circular shape in a plan view. The stage 3 is supported by a support 31. A top surface 3a of the stage 3 is provided with a substantially circular recess 32 for receiving the substrate W, which has, for example, a diameter of 300 millimeters (mm). The recess 32 has an inner diameter that is slightly greater (e.g., about 1 mm or greater and 4 mm or less) than the diameter of the substrate W. The depth of the recess 32 is, for example, substantially the same as the thickness of the substrate W. Also, the stage 3 is formed of a ceramic material, such as aluminum nitride (AlN) or the like. Alternatively, the stage 3 may be formed of a metal material, such as nickel (Ni) or the like. Rather than the recess 32, a guide ring configured to guide the substrate W may be provided at the circumferential edge of the top surface 3a of the stage 3.

For example, a grounded lower electrode 33 is embedded in the stage 3. A temperature adjusting mechanism 34 is embedded below the lower electrode 33. The temperature adjusting mechanism 34 is configured to adjust the stage 3 or the substrate W placed on the stage 3 to a set temperature in accordance with a control signal from a controller 9. When the entirety of the stage 3 is formed of a metal, the entirety of the stage 3 functions as a lower electrode. Thus, there is no need to embed the lower electrode 33 in the stage 3. The stage 3 is provided with a plurality of (e.g., three) raising and lowering pins 41 configured to hold and raise/lower the substrate W placed on the stage 3. The material of the raising and lowering pins 41 may be, for example, ceramics, such as alumina (Al₂O₃) or the like, or quartz. The lower ends of the raising and lowering pins 41 are attached to a support plate 42. The support plate 42 is connected to a raising and lowering mechanism 44 provided outside the processing chamber 2 via a raising and lowering shaft 43.

The raising and lowering mechanism 44 is, for example, provided below the gas exhaust chamber 21. A bellows 45 is provided between: an opening 21a, for passage of the raising and lowering shaft 43, formed in the bottom surface of the gas exhaust chamber 21; and the raising and lowering mechanism 44. The shape of the support plate 42 may be a shape in which the support plate 42 can raise and lower without interfering with the support 31 of the stage 3. The raising and lowering pins 41 are configured to raise and lower by the raising and lowering mechanism 44 between an upper side of the top surface 3a of the stage 3 and a lower side of the top surface 3a of the stage 3. In other words, the raising and lowering pins 41 are configured to project beyond the top surface 3a of the stage 3.

A top wall 27 of the processing chamber 2 is provided with a gas supply 5 via an insulating member 28. The gas supply 5 forms an upper electrode and faces the lower electrode 33. An RF power supply 51 is connected to the gas supply 5 via a matcher 52. The frequency band of the RF power supply 51 is, for example, 450 kHz or higher and 2.45 GHz or lower. Supply of RF power from the RF power supply 51 to the gas supply 5 generates an RF electric field between the gas supply 5 and the lower electrode 33. The gas supply 5 includes a hollow gas diffusion chamber 53. The bottom surface of the gas diffusion chamber 53 is provided with many holes 54 for supplying and dispersing a processing gas in the processing chamber 2. The holes 54 are provided, for example, in equal intervals. A heating mechanism 55 is embedded in the gas supply 5, for example, above the gas diffusion chamber 53. The heating mechanism 55 is heated to a set temperature by supply of power from a power supply (not shown) in accordance with a control signal from the controller 9.

The gas diffusion chamber 53 is provided with a gas supply path 6. The gas supply path 6 communicates with the gas diffusion chamber 53. A gas source 61 is connected upstream the gas supply path 6 via a gas line 62. The gas source 61 includes, for example, supply sources of various processing gases, a mass flow controller, and a valve (which are not shown). The processing gas includes gases used in the substrate processing methods according to the first example and the second example of the embodiment. The processing gas is introduced from the gas source 61 into the gas diffusion chamber 53 via the gas line 62.

The controller 9 or the controller CT is an electronic circuit or circuitry (including a processor), such as a central processing unit (CPU), a field programmable gate array (FPGA), an application specific integrated circuit (ASIC), or the like. The controller 9 or the controller CT is configured to execute various controls described in the present specification by executing instruction codes stored in a memory or by being designed as a circuit for specific applications.

### [Operation of Substrate Processing Apparatus]

Operation of the substrate processing apparatus 1 will be described when the substrate processing apparatus 1 performs step S12 of the substrate processing method according to the embodiment.

First, the controller 9 opens the gate valve 26, and causes a transfer mechanism (not shown) to transfer the substrate W into the processing chamber 2 to place the substrate W on the stage 3. The substrate W may be the substrate 100 provided in step S11 as described above. The controller 9 retracts the transfer mechanism from the processing chamber 2, and closes the gate valve 26.

Next, the controller 9 controls each component of the substrate processing apparatus 1 to perform step S12 as described above on the substrate W, which is placed on the stage 3 in the processing chamber 2.

Next, the controller 9 transfers the substrate W out of the processing chamber 2 in reverse to the procedure for transferring the substrate W into the processing chamber 2. As such, step S12 is performed on the single substrate W.

### Experimental Results

### (Experiment A)

In Experiment A, samples A1 to A4 below were prepared, and cross sections of samples A1 to A4 were observed.

### <Sample A1>

First, a substrate including an etching target film and a base film formed over the etching target film and including top surfaces and side surfaces was provided. The base film was a silicon oxide film. Next, step S12 as described above was performed to form a 100 nm-thick carbon film over the top surfaces of the silicon oxide film selectively relative to the side surfaces of the silicon oxide film. Next, step S13 as described above was performed to thermally process the carbon film. Next, step S14 as described above was performed to form a 300 nm-thick carbon film over the top surfaces of the 100 nm-thick carbon film with respect to the side surfaces of the 100 nm-thick carbon film. Conditions for step S12, conditions for step S13, and conditions for step S14 are as follows.

### Conditions for Step S12 and Conditions for Step S14

Propylene gas: 11 sccm
Helium gas: 330 sccm
Hydrogen gas: 11 sccm
Pressure: 0.5 Torr
RF power: 300 W (40 MHz or higher)
Substrate temperature (first temperature): 400° C.

### Conditions for Step S13

Argon gas: 1,800 sccm
Pressure: 2 Torr
Substrate temperature: 550° C.
Period: 60 minutes

### <Sample A2>

First, the same substrate as that used for sample A1 was provided. Next, steps S12, S13, and S14 as described above were performed. For sample A2, a period of step S13 was changed from 60 minutes to 30 minutes unlike in the preparation of sample A1. Conditions for step S12, conditions for step S13, and conditions for step S14 are the same as the conditions for the preparation of sample A1 except for the period of step S13.

### <Sample A3>

First, the same substrate as that used for sample A1 was provided. Next, steps S12, S13, and S14 as described above were performed. For sample A3, a period of step S13 was changed from 60 minutes to 10 minutes unlike in the preparation of sample A1. Conditions for step S12, conditions for step S13, and conditions for step S14 are the same as the conditions for the preparation of sample A1 except for the period of step S13.

### <Sample A4>

First, the same substrate as that used for sample A1 was provided. Next, steps S12 and S14 as described above were performed. For sample A2, step S13 was not performed unlike in the preparation of sample A1. Conditions for step S12 and conditions for step S14 are the same as the conditions for the preparation of sample A1.

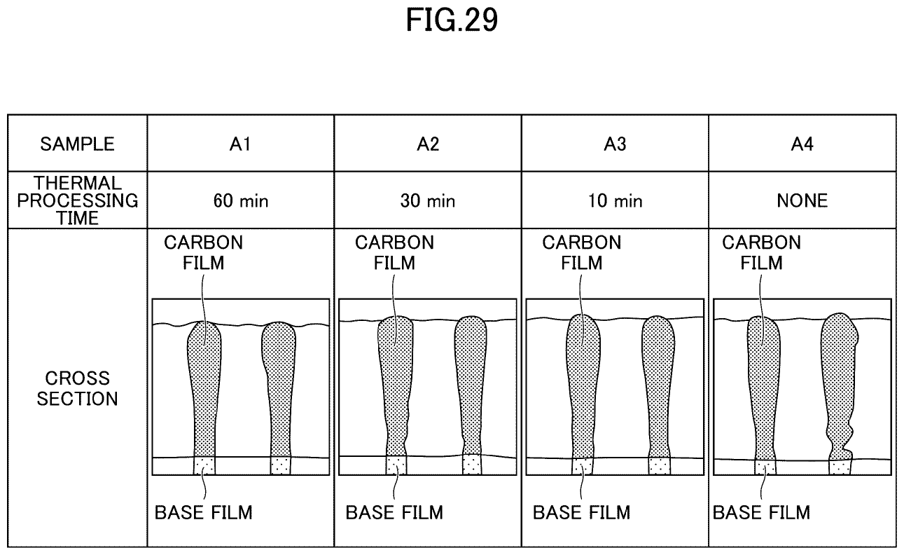

FIG. 29 is a table illustrating the results obtained by observing the cross sections of the carbon films. The cross section of each sample was observed with a scanning electron microscope (SEM). FIG. 29 schematically illustrates an SEM image of the cross section of each sample.

As illustrated in FIG. 29, no defect is caused in the root portions of the carbon films of samples A1 to A3, while the root portions of the carbon film of sample A4 are thinned to have defects. This result indicates that thermally processing the carbon film to eliminate hydrogen partway through the formation of the carbon film can reduce defects in the root portions of the carbon film when forming the carbon film over the top surfaces of the patterned base film.

### (Experiment B)

In Experiment B, samples B1 to B3 below were prepared, and film compositions and film densities of samples B1 to B3 were measured.

### <Sample B1>

First, a substrate including a base film having a flat top surface was provided. The base film was a silicon oxide film. Next, step S12 as described above was performed to form a 100 nm-thick carbon film over the top surfaces of the silicon oxide film. Next, step S13 as described above was performed to thermally process the carbon film. Conditions for step S12 and conditions for step S13 are as follows.

### Conditions for Step S12

Propylene gas: 11 sccm
Helium gas: 330 sccm
Hydrogen gas: 11 sccm
Pressure: 0.5 Torr
RF power: 300 W (40 MHz or higher)
Substrate temperature (first temperature): 400° C.

### Conditions for Step S13

Argon gas: 1,800 sccm
Pressure: 2 Torr
Substrate temperature: 550° C.
Period: 60 minutes

### <Sample B2>

First, the same substrate as that used for sample B1 was provided. Next, steps S12 and S13 as described above were performed. For sample B2, a period of step S13 was changed from 60 minutes to 30 minutes unlike in the preparation of sample B1. Conditions for step S12 and conditions for step S13 are the same as the conditions for the preparation of sample B1 except for the period of step S13.

### <Sample B3>

First, the same substrate as that used for sample B1 was provided. Next, step S12 as described above was performed. For sample B2, step S13 was not performed unlike in the preparation of sample B1. Conditions for step S12 were the same as the conditions for the preparation of sample B1.

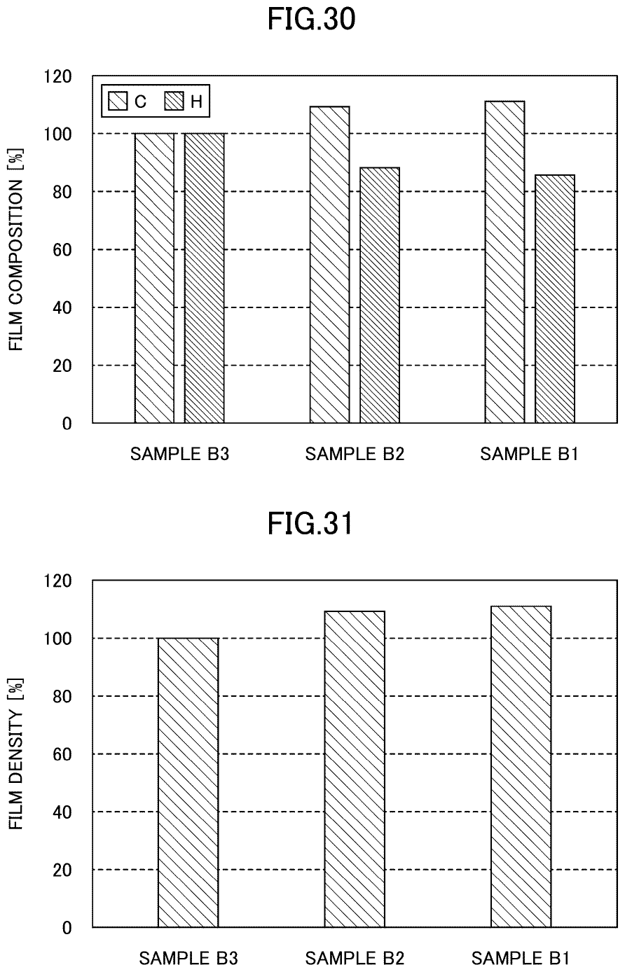

FIG. 30 is a graph illustrating the results obtained by measuring the compositions of the carbon films. The composition of the carbon film of each sample was measured through Rutherford back-scattering spectroscopy (RBS) and hydrogen forward-scattering spectroscopy (HFS). In FIG. 30, the carbon (C) content and the hydrogen (H) content of each sample are shown as relative values [%], with each of the carbon content and the hydrogen content of sample B3 being 100%.

As illustrated in FIG. 30, the carbon content is higher in samples B1 and B2 than in sample B3, and the hydrogen content is lower in samples B1 and B2 than in sample B3. This result indicates that the thermal processing of the carbon film eliminates hydrogen from the carbon film.

FIG. 31 is a graph illustrating the results obtained by measuring the densities of the carbon films. The density of the carbon film of each sample was calculated based on the composition measured through Rutherford back-scattering spectroscopy and hydrogen forward-scattering spectroscopy and based on the film thickness of the carbon film. In FIG. 31, the film density of each sample is shown as a relative value [%], with the film density of sample B3 being 100%.

As illustrated in FIG. 31, the film densities of the carbon films of samples B1 and B2 are higher than the film density of sample B3. This result indicates that the thermal processing of the carbon film densifies the carbon film.

In the above embodiments, the carbon film 103 is an example of a first carbon film, and the carbon film 104, the carbon film 104-1, the carbon film 104-2, the carbon film 104-3, or the carbon film 104-4 is an example of a second carbon film.

The embodiments disclosed herein should be considered exemplary and not restrictive in all respects. Omissions, substitutions, and modifications can be made to the above embodiments in various forms without departing from the scope and intent of claims recited.

Although the above embodiments have been described based on the case in which the substrate processing apparatus 1 includes the single stage 3 in the processing chamber 2, the present disclosure is not limited to this. For example, the substrate processing apparatus 1 may include, in the processing chamber 2, the two stages 3 configured to be independently controllable in temperature. In this case, the formation of the carbon film 103 (step S12 in FIG. 1) and the formation of the carbon film 104 (step S14 in FIG. 1) may be performed on the substrate W placed on one of the stages 3. Also, the elimination of hydrogen from the carbon film (steps S13 and S15 in FIG. 1) may be performed on the substrate W placed on the other stage 3. Further, for example, the substrate processing apparatus 1 may include, in the processing chamber 2, the three or more stages 3 configured to be independently controllable in temperature.

According to the present disclosure, it is possible to reduce defects in the root portion of the carbon film when forming the carbon film over the top surfaces of the patterned base film.

What is claimed is:

1. A substrate processing method, comprising:
providing a substrate including an etching target film and a base film that is formed over the etching target film and includes a top surface and a side surface;
exposing the substrate to a plasma generated from a film-forming gas containing a raw material gas containing carbon and hydrogen, thereby forming a first carbon film over the top surface of the base film selectively relative to the side surface of the base film;
thermally processing the substrate to eliminate the hydrogen from the first carbon film;
exposing the substrate to the plasma to form a second carbon film over the first carbon film; and
etching the etching target film using, as masks, the base film, the first carbon film, and the second carbon film.

2. The substrate processing method according to claim 1, further comprising:
before the etching of the etching target film, thermally processing the substrate to eliminate the hydrogen from the second carbon film.

3. The substrate processing method according to claim 1, wherein
a film thickness of the second carbon film is greater than a film thickness of the first carbon film.

4. The substrate processing method according to claim 2, wherein
the formation of the second carbon film and the elimination of the hydrogen from the second carbon film are sequentially performed a plurality of times.

5. The substrate processing method according to claim 4, wherein
a film thickness of the second carbon film is equal to a film thickness of the first carbon film.

6. The substrate processing method according to claim 1, wherein
a temperature at which the hydrogen is eliminated from the first carbon film is higher than a temperature at which the first carbon film is formed.

7. The substrate processing method according to claim 1, wherein
the elimination of the hydrogen from the first carbon film is performed in an atmosphere of an inert gas.

8. The substrate processing method according to claim 7, wherein
the inert gas is an argon gas.

9. The substrate processing method according to claim 1, wherein
the raw material gas is a hydrocarbon gas.

10. The substrate processing method according to claim 1, wherein
the base film is an amorphous carbon film.

11. The substrate processing method according to claim 1, wherein
the formation of the first carbon film and the elimination of the hydrogen from the first carbon film are performed in a single processing chamber.

12. A substrate processing apparatus configured to etch an etching target film formed over a substrate, including the etching target film and a base film that is formed over the etching target film and includes a top surface and a side surface, the substrate processing apparatus comprising:
a controller including circuitry configured to:
expose the substrate to a plasma generated from a film-forming gas containing a raw material gas containing carbon and hydrogen, thereby forming a first carbon film over the top surface of the base film selectively relative to the side surface of the base film;
thermally process the substrate to eliminate the hydrogen from the first carbon film;
expose the substrate to the plasma to form a second carbon film over the first carbon film; and
etch the etching target film using, as masks, the base film, the first carbon film, and the second carbon film.

13. A substrate processing system configured to etch an etching target film formed over a substrate, including the etching target film and a base film that is formed over the etching target film and includes a top surface and a side surface, the substrate processing system comprising:
a controller;
a first processor;
a second processor;
a third processor; and
a fourth processor, wherein
the controller includes circuitry configured to:
cause the first processor to expose the substrate to a plasma generated from a film-forming gas containing a raw material gas containing carbon and hydrogen, thereby forming a first carbon film over the top surface of the base film selectively relative to the side surface of the base film;
cause the second processor to thermally process the substrate to eliminate the hydrogen from the first carbon film;
cause the third processor to expose the substrate to the plasma to form a second carbon film over the first carbon film; and
cause the fourth processor to etch the etching target film using, as masks, the base film, the first carbon film, and the second carbon film.
